(19) United States
(12) Patent Application Publication
(10) Pub. No.: US 2012/0049199 A1
(43) Pub. Date: Mar. 1, 2012

(54) Method of forming polycrystalline silicon layer, method of manufacturing thin film transistor including the method, thin-film transistor manufactured by using the method of manufacturing thin-film transistor, and organic light-emitting display device including the thin-film transistor

(76) Inventors: Yun-Mo Chung, Yongin-City (KR); Ki-Yong Lee, Yongin-City (KR); Jin-Wook Seo, Yongin-City (KR); Min-Jae Jeong, Yongin-City (KR); Seung-Kyu Park, Yongin-City (KR); Yong-Duck Son, Yongin-City (KR); Byung-Soo So, Yongin-City (KR); Byoung-Keon Park, Yongin-City (KR); Kil-Won Lee, Yongin-City (KR); Dong-Hyun Lee, Yongin-City (KR); Tak-Young Lee, Yongin-City (KR); Jong-Ryuk Park, Yongin-City (KR)

(21) Appl. No.: 13/137,428

(22) Filed: Aug. 15, 2011

(30) Foreign Application Priority Data
Aug. 31, 2010 (KR) 10-2010-0084892

(51) Int. Cl. H01L 21/20; H01L 29/04; H01L 33/16; H01L 29/786; H01L 21/336

(52) U.S. Cl. 257/72; 438/486; 257/66; 438/166; 257/E21.09; 257/E21.413; 257/E29.003; 257/E29.293; 257/E33.003

(57) ABSTRACT

A method of forming a polycrystalline layer includes forming a buffer layer on a substrate; treating the buffer layer with hydrogen plasma; forming an amorphous silicon layer on the buffer layer; forming a metallic catalyst layer for crystallizing the amorphous silicon layer on the amorphous silicon layer; and heat treating the amorphous silicon layer to form a polycrystalline silicon layer.

### BACKGROUND

1. Field

Aspects of the present invention relate to a method of forming a polycrystalline silicon layer using a metallic catalyst, a method of manufacturing a thin film transistor including the method, a thin-film transistor manufactured by using the method of manufacturing a thin-film transistor, and an organic light-emitting display device including the thin-film transistor.

2. Description of the Related Art

In general, a thin-film transistor that includes a polycrystalline silicon layer has high electron mobility and enables formation of a CMOS circuit. Due to these characteristics, such a thin-film transistor is used in a switching device of a high-definition display panel or a projection panel that requires a great amount of light.

An amorphous silicon may be crystallized into a polycrystalline silicon by using many methods including: solid phase crystallization (SPC) in which an amorphous silicon layer is annealed for a few to tens of hours at a temperature equal to or lower than about 700° C. at which glass, which is used to form a substrate of a display device including a thin-film transistor, is transformed; excimer laser annealing (ELA) in which an amorphous silicon layer is locally heated at a high temperature for a very short time period by scanning the amorphous silicon layer with an excimer laser; metal-induced crystallization (MIC) in which metal, such as nickel, palladium, gold, or aluminum, is brought into contact with or is implanted in an amorphous silicon layer so as to induce a phase change from the amorphous silicon layer into a polycrystalline silicon layer; and metal-induced lateral crystallization (MILC) in which crystallization of an amorphous silicon is induced while silicide, which is generated by reacting metal with silicon, continues to laterally diffuse.

However, in regard to the SPC, the process time may be too long, and the high-temperature heat treatment for a long time period may lead to deformation of a substrate; in regard to ELA, an expensive laser apparatus is required and protrusions may be formed on a polycrystalline surface and an interface between a semiconductor layer and a gate insulating layer may have poor characteristics; and in regard to MIC and MILC, a great amount of metallic catalyst may remain on the polycrystalline silicon layer and a leakage current of a thin-film transistor may be increased.

In order to solve contamination by a metallic catalyst in MILC, super grain silicon (SGS) crystallization was developed in which the concentration of a metallic catalyst diffusing into an amorphous silicon layer may be controlled to be at low levels so as to control the size of crystal grain growing from a metal seed to be a few μm to hundreds μm.

However, in SGS crystallization, crystals grow based on a metal seed in a radial direction and thus crystals of neighboring crystal grains may grow randomly. Due to the different crystal growth directions of a polycrystalline silicon layer, a thin-film transistor including a polycrystalline silicon layer crystallized by SGS crystallization may have varying characteristics.

### SUMMARY

Embodiments are directed to a method of forming a polycrystalline silicon layer in which at least two neighboring crystal grains have the same crystal direction, a method of manufacturing a thin-film transistor including the method, a thin-film transistor manufactured by using the method of manufacturing a thin-film transistor, and an organic light-emitting display device including the thin-film transistor.

According to an embodiment, there is provided a method of forming a polycrystalline layer, the method including forming a buffer layer on a substrate, treating the buffer layer with hydrogen plasma, forming an amorphous silicon layer on the buffer layer, forming a metallic catalyst layer for crystallizing the amorphous silicon layer on the amorphous silicon layer, and heat treating the amorphous silicon layer to form a polycrystalline silicon layer.

The buffer layer formed on the substrate may include at least one of silicon oxide, silicon nitride, and silicon oxynitride.

A surface concentration of the metallic catalyst layer formed on the amorphous silicon layer may be in a range of 10¹¹ to 10¹⁵ atoms/cm².

The metallic catalyst layer formed on the amorphous silicon layer may include at least one of Ni, Pd, Ti, Ag, Al, Sn, Sb, Cu, Co, Mo, Tb, Ru, Rh, Cd, and Pt.

According to an embodiment, there is provided a thin-film transistor including a substrate, a buffer layer comprising hydrogen on the substrate, a semiconductor layer on the buffer layer, the semiconductor layer comprising a channel region and source and drain regions neighboring the channel region, and comprising a plurality of crystal grains crystallized from amorphous silicon using a metallic catalyst as a seed, wherein at least two neighboring crystal grains have the same crystal direction, a gate insulating layer on the buffer layer and covers the semiconductor layer, a gate electrode on the gate insulating layer, corresponding to the channel region, an interlayer insulating layer on the gate insulating layer and covers the gate electrode, and source and drain electrodes on the interlayer insulating layer and electrically connected to the source region and the drain region, respectively.

The buffer layer may include at least one of silicon oxide, silicon nitride, and silicon oxynitride.

The metallic catalyst may be at least one of Ni, Pd, Ti, Ag, Al, Sn, Sb, Cu, Co, Mo, Tb, Ru, Rh, Cd, and Pt.

The semiconductor layer may have more neighboring crystal grains having a same crystal direction than does a semiconductor layer that is formed on a buffer layer that does not comprise hydrogen.

Crystal directions of crystal grains of the semiconductor layer may have a crystal direction heterogeneity factor D of less than 20 as measured by an electron backscattered diffraction (EBSD) analysis system, according to the formula D=(N/n)×1000, where n is a total number of pixels evaluated in the electron backscattered diffraction (EBSD) analysis system and N is a number of instances in which a crystal direction reference factor, calculated as a maximum difference value among difference values of R, G, and B values of the evaluated pixels, is equal to or greater than 150.

According to an embodiment, there is provided a method of forming a thin-film transistor, the method including forming a buffer layer on a substrate, treating the buffer layer with hydrogen plasma, forming an amorphous silicon layer on the buffer layer, forming a metallic catalyst layer for crystallizing the amorphous silicon layer on the amorphous silicon layer, heat treating the amorphous silicon layer to form a polycrystalline silicon layer, removing the metallic catalyst layer and patterning the polycrystalline silicon layer to form a semiconductor layer comprising source and drain regions and a channel region, forming a gate insulating layer covering the semiconductor layer, forming a gate electrode on the gate insulating layer, corresponding to the channel region of the semiconductor layer, forming an interlayer insulating layer covering the gate electrode on the gate insulating layer, and forming source and drain electrodes disposed on the interlayer insulating layer and electrically connected to the source and drain regions of the semiconductor layer, respectively.

The buffer layer formed on the substrate may include at least one of silicon oxide, silicon nitride, and silicon oxynitride.

A surface concentration of the metallic catalyst layer formed on the amorphous silicon layer may be in a range of 10¹¹ to 10¹⁵ atoms/cm².

The metallic catalyst layer formed on the amorphous silicon layer may include at least one of Ni, Pd, Ti, Ag, Al, Sn, Sb, Cu, Co, Mo, Tb, Ru, Rh, Cd, and Pt.

According to an embodiment, there is provided an organic light-emitting display device including a substrate, a buffer layer comprising hydrogen on the substrate, a semiconductor layer on the buffer layer, the semiconductor layer comprising a channel region and source and drain regions neighboring the channel region, and comprising a plurality of crystal grains crystallized from an amorphous silicon using a metallic catalyst as a seed, wherein at least two neighboring crystal grains have the same crystal direction, a gate insulating layer on the buffer layer and covering the semiconductor layer, a gate electrode that is formed on the gate insulating layer, corresponding to the channel region, an interlayer insulating layer on the gate insulating layer and covering the gate electrode, source and drain electrodes on the interlayer insulating layer and electrically connected to the source region and the drain region, respectively, a passivation layer on the gate insulating layer, covering the source and drain electrodes, a pixel electrode on the passivation layer and electrically connected to the source electrode or the drain electrode through a via-hole, and an organic layer on the pixel electrode and comprising an emissive layer.

The buffer layer may include silicon oxide, silicon nitride, or silicon oxynitride.

The metallic catalyst may include at least one of Ni, Pd, Ti, Ag, Al, Sn, Sb, Cu, Co, Mo, Tb, Ru, Rh, Cd, and Pt.

The semiconductor layer may have more neighboring crystal grains having a same crystal direction than does a semiconductor layer that is formed on a buffer layer that does not comprise hydrogen.

Crystal directions of crystal grains of the semiconductor layer may have a crystal direction heterogeneity factor D of less than 20, as measured by an electron backscattered diffraction (EBSD) analysis system, according to the formula D=(N/n)×1000, where n is a total number of pixels evaluated in an electron backscattered diffraction (EBSD) analysis system and N is a number of instances in which a crystal direction reference factor, calculated as a maximum difference value among difference values of R, G, and B values of the evaluated pixels, is equal to or greater than 150.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 through 6 illustrate schematic sectional views to explain a method of forming a polycrystalline silicon layer by super grain silicon (SGS) crystallization, according to an embodiment of the present invention;

FIG. 7 illustrates electron backscattered diffraction (EBSD) analysis results of a polycrystalline silicon layer when a buffer layer is not treated with hydrogen plasma;

FIG. 8 illustrates EBSD analysis results of a polycrystalline silicon layer when a buffer layer is treated with hydrogen plasma;

FIG. 9A illustrates an enlarged view of region A of FIG. 7 and FIG. 9B illustrates an enlarged view of region B of FIG. 8;

FIGS. 10 through 12 illustrate sectional views to explain a method of manufacturing a thin-film transistor by SGS crystallization, according to an embodiment of the present invention;

FIG. 13 illustrates a schematic sectional view of an organic light-emitting display device including the thin-film transistor, according to an embodiment of the present invention; and

FIG. 14 illustrates a graph showing DR RANGE characteristics of a thin-film transistor manufactured by using a method of forming a polycrystalline silicon layer according to an embodiment of the present invention.

### DETAILED DESCRIPTION

Korean Patent Application No. 10-2010-0084892, filed on Aug. 31, 2010, in the Korean Intellectual Property Office, and entitled: “Method of Forming Polycrystalline Silicon Layer, Method of Manufacturing Thin Film Transistor Including the Method, Thin-Film Transistor Manufactured by Using the Method of Manufacturing Thin-Film Transistor, and Organic Light-Emitting Display Device Including the Thin-Film Transistor,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

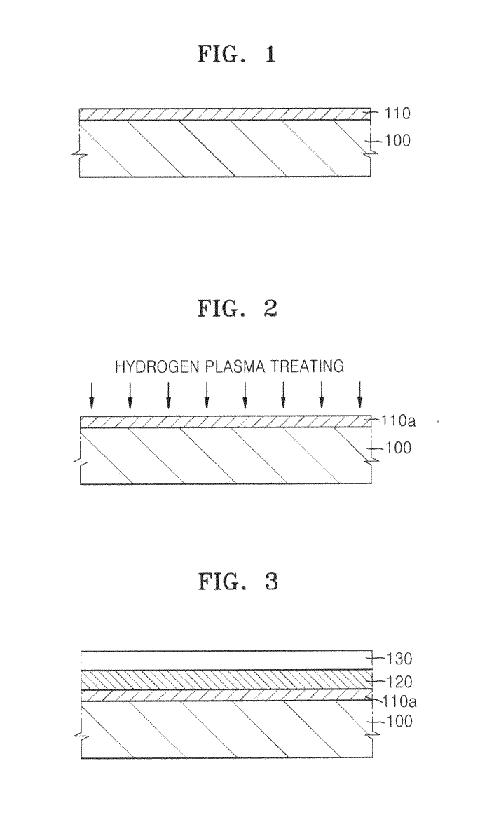

FIGS. 1 through 6 illustrate schematic sectional views to explain a method of forming a polycrystalline silicon layer by super grain silicon (SGS) crystallization, according to an embodiment of the present invention.

Referring to FIGS. 1 and 2, a buffer layer 110 is formed on a substrate 100, and the buffer layer 110 is treated with hydrogen plasma.

The substrate 100 may be formed of a transparent glass material that mainly consists of SiO₂, but is not limited thereto.

The buffer layer 110 may prevent permeation of impurity elements from the substrate 100 and planarize a surface of the substrate 100, and may include silicon nitride or silicon oxynitride.

The buffer layer 110 may include silicon oxide, and before an amorphous silicon layer 120 is formed, the buffer layer 110 may be treated with hydrogen plasma so that a high concentration of hydrogen is implanted in the buffer layer 110. As a result, the buffer layer 110a with a high concentration of hydrogen may be formed.

Referring to FIGS. 3 and 4, the amorphous silicon layer 120 may be formed on the buffer layer 110a with a high concentration of hydrogen, a thermal oxidation layer 130 may be formed on the amorphous silicon layer 120, and a metallic catalyst layer 140 including a metallic catalyst 141 may be formed on the thermal oxidation layer 130.

The amorphous silicon layer 120 may be formed by chemical vapor deposition (CVD), and the amorphous silicon layer 120 may be formed by CVD including a gas such as hydrogen. The gas may cause a reduction in electron mobility. Thus, in order to prevent the presence of the gas in the amorphous silicon layer 120, a dehydrogenation process may be performed. However, the dehydrogenation process is optional and may not be performed herein.

Next, under an atmosphere including an oxygen gas or a water vapor and an inert gas such as argon gas, the amorphous silicon layer 120 may be thermally oxidized to form the thermal oxidation layer 130. The thermal oxidation layer 130 may control the concentration of a metallic catalyst diffusing into the amorphous silicon layer 120 and may function as a capping layer. A detailed description of the metallic catalyst will be described in detail below. However, since the thermal oxidation layer 130 may be formed with a smaller thickness than a conventional capping layer, a more uniform layer quality may be obtained than the conventional capping layer and thus the metallic catalyst 141 may uniformly diffuse.

In the present embodiment, the concentration of the metallic catalyst may be controlled by using the thermal oxidation layer 130. However, the present invention is not limited thereto. That is, instead of the thermal oxidation layer 130, a conventional capping layer that is formed of silicon nitride may be used.

In addition, where the concentration of the metallic catalyst 141 is controllable, without the formation of the thermal oxidation layer 130 or the conventional capping layer, the metallic catalyst 141 may be directly formed with a desired concentration on the amorphous silicon layer 120. For example, the metallic catalyst 141 may be deposited on the amorphous silicon layer 120 by atomic layer deposition (ALD), which enables deposition with a constant atomic-level thickness, or by sputtering the metallic catalyst 141 as a target.

The concentration of the metallic catalyst 141 at the surface of the metallic catalyst layer 140 may be in the range of 10¹¹ to 10¹⁵ atoms/cm². If the surface concentration of the metallic catalyst 141 is less than 10¹¹ atoms/cm², the amount of a seed, which is a crystalline nucleus, may be too small and crystallization may not occur. On the other hand, if surface concentration of the metallic catalyst 141 is greater than 10¹⁵ atoms/cm¹⁵, the amount of the metallic catalyst 141 diffusing into the amorphous silicon layer 120 may be high and thus crystallization may occur by metal-induced crystallization (MIC) and more metallic catalyst 141 may remain.

The metallic catalyst 141 may include one material selected from the group consisting of Ni, Pd, Ti, Ag, Al, Sn, Sb, Cu, Co, Mo, Tb, Ru, Rh, Cd, and Pt. For example, the metallic catalyst 141 may be Ni.

Referring to FIGS. 5 and 6, the metallic catalyst layer 140 formed as described above may be heat treated to crystallize the amorphous silicon layer 120 into a polycrystalline silicon layer 220.

During the heat treatment, a metallic catalyst 141a may go through the thermal oxidation layer 130 and diffuse into the amorphous silicon layer 120. Some of the metallic catalyst, indicated as 141b in FIG. 5, may remain in the thermal oxidation layer 130. Although not illustrated in FIG. 5, some of the metallic catalyst 141 may remain in the metallic catalyst layer 140.

In this case, due to the metallic catalyst 141a that reaches the amorphous silicon layer 120 through the thermal oxidation layer 130, the amorphous silicon layer 120 may be crystallized into the polycrystalline silicon layer 220. That is, the metallic catalyst 141a may be combined with silicon in the amorphous silicon layer 120 to form a metallic silicide, which forms a seed, which is a crystalline nucleus, thereby crystallizing the amorphous silicon layer 120 into the polycrystalline silicon layer 220.

In this regard, the heat treatment process may be any one process selected from the group consisting of a furnace process, a rapid thermal annealing (RTA) process, an ultraviolet (UV) process, and a laser process.

The heat treatment process may consist of two steps: a first heat treatment step and a second heat treatment step. In the first heat treatment step, the metallic catalyst 141 in the metallic catalyst layer 140 may migrate to an interface between the thermal oxidation layer 130 and the amorphous silicon layer 120 so as to form a seed, and in the second heat treatment step, due to the seed, the amorphous silicon layer 120 may be crystallized into the polycrystalline silicon layer 220. In this regard, the first heat treatment step may be performed in the range of 200° C. to 800° C., and the second heat treatment process may be performed in the range of 400° C. to 1300° C.

After the crystallization, the thermal oxidation layer 130 and the metallic catalyst layer 140 may be removed.

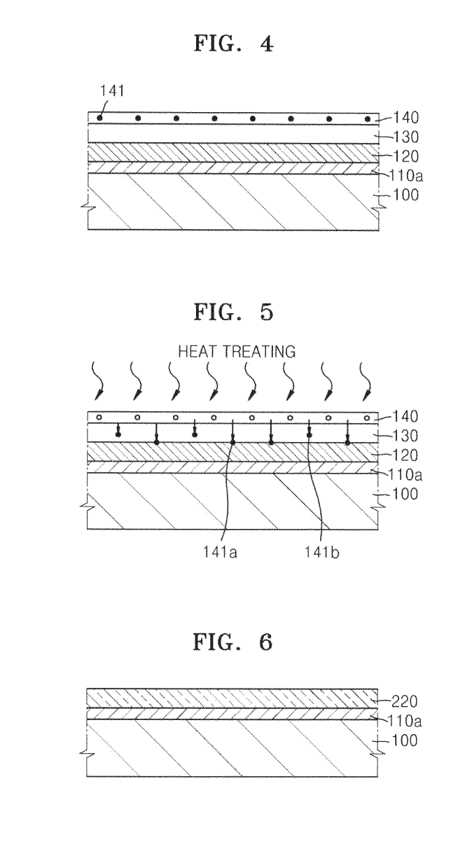

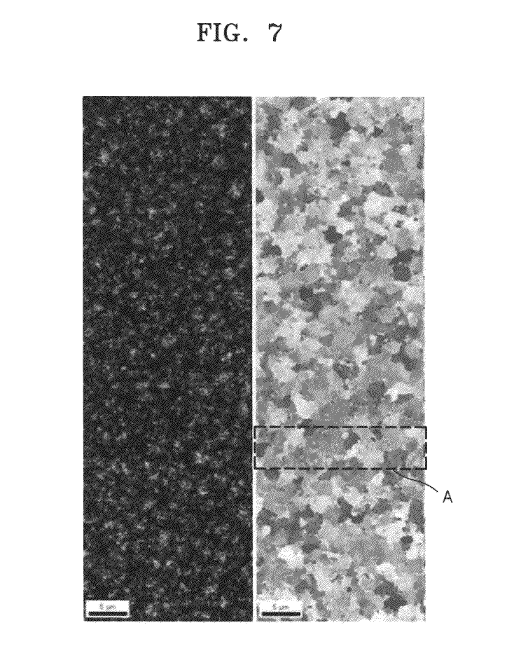

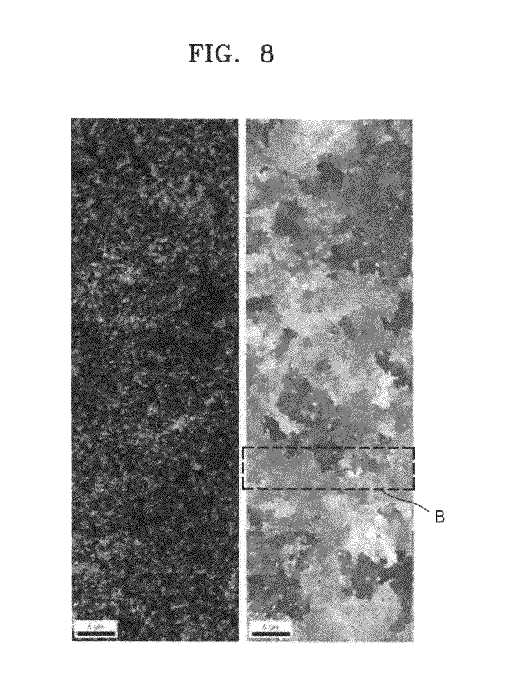

FIG. 7 shows an SEM image (left image) and electron backscattered diffraction (EBSD) analysis results (right image) of a polycrystalline silicon layer when a buffer layer is not treated with hydrogen plasma. FIG. 8 shows an SEM image (left image) and EBSD analysis results (right image) of a polycrystalline silicon layer when a buffer layer is treated with hydrogen plasma. FIG. 9 shows enlarged views of regions A and B of FIGS. 7 and 8. In both instances, the metallic catalyst 141 was Ni.

In FIGS. 7 and 8, right images show a plurality of crystal grains formed in the respective polycrystalline silicon layers, in which crystal grains with the same crystal direction have the same color. According to FIGS. 7 and 8, when the buffer layer is treated with hydrogen plasma, crystal grains with the same crystal direction in the polycrystalline silicon layer are continuously present in a wider region (FIG. 8) than when the buffer layer is not treated with hydrogen plasma (FIG. 7). Crystal grains having similar colors with a small gradation shown are present in fewer groups and in a wider region in FIG. 8 than in FIG. 7.

According to an EBSD analysis, crystal directions of crystal grains, for example, (1,0,0), (1,1,0), and (1,1,1) may be represented as corresponding to red (R) (255,0,0), green (G) (0,255,0), and blue (B) (0,0,255) values. R, G, and B values of neighboring pixels in an EBSD analysis system are measured and then a maximum difference value among difference values of R, G, and B values of neighboring crystal grains is measured, and if the maximum difference value is equal to or greater than 150, that is, a crystal direction reference factor S which is referred when a crystal direction change is determined, it is determined that neighboring pixels have different crystal directions and the number N of the case is counted. In this regard, if the N is large, it is determined that neighboring pixels have many different crystal directions, and if the N is small, it is determined that neighboring pixels have similar crystal directions.

A crystal direction heterogeneity factor D may defined by dividing the counted number N by the total number of counted pixels n (N/n) and multiplying N/n by 1000. In applying EBSD analysis to the right sample of FIG. 7 and the right sample of FIG. 8, it was calculated that D of the right sample of FIG. 7 was 20 and D of the right sample of FIG. 8 was 12. When the buffer layer is plasma treated, the crystal direction heterogeneity of the polycrystalline silicon layer 120 is lower than when the buffer layer is not plasma treated. Crystal grains of the polycrystalline silicon layer 120 have similar crystal directions.

Accordingly, when a buffer layer is treated with hydrogen plasma and a semiconductor layer is crystallized as in the present embodiment, the semiconductor layer may have a crystal direction heterogeneity factor D of less than 20, which is obtained by EBSD analysis.

FIG. 9A illustrates an enlarged view of region A of FIG. 7 and FIG. 9B illustrates an enlarged view of region B of FIG. 8. Referring to FIGS. 9A and 9B, when regions A′ and B′ of the polycrystalline silicon layers of FIGS. 9A and 9B are compared, when a buffer layer is not treated with hydrogen plasma (see FIG. 9A), crystal grains have four crystal directions d1, d2, d3 and d4, and when a buffer layer is treated with hydrogen plasma (see FIG. 9B), crystal grain crystal grains may have the same crystal direction d5 over larger areas of the sample. Although FIG. 9A illustrates four crystal directions d1, d2, d3 and d4 in region A′, the illustration in FIGS. 9A is a very schematic view of crystal grains for ease of description, and thus, as illustrated in region A in FIG. 7, more crystal directions may be present in reality in the semiconductor region represented by FIG. 9A.

Without being bound to any particular theory, a possible hypothesis for this phenomenon is that hydrogen atoms or hydrogen molecules that may be present inside the structure of SiO₂, or that may be bonded to Si— or O— in the buffer layer 110a with a higher concentration of hydrogen due to the hydrogen plasma treatment, may decompose and diffuse into the amorphous silicon layer 120.

As a result, according to the method of forming the polycrystalline silicon layer 120 in which the buffer layer 110 may be treated with hydrogen plasma and then the amorphous silicon layer 120 may be crystallized into the polycrystalline silicon layer 220 using the metallic catalyst 141, at least two neighboring crystal grains in the polycrystalline silicon layer 220 may have the same crystal direction.

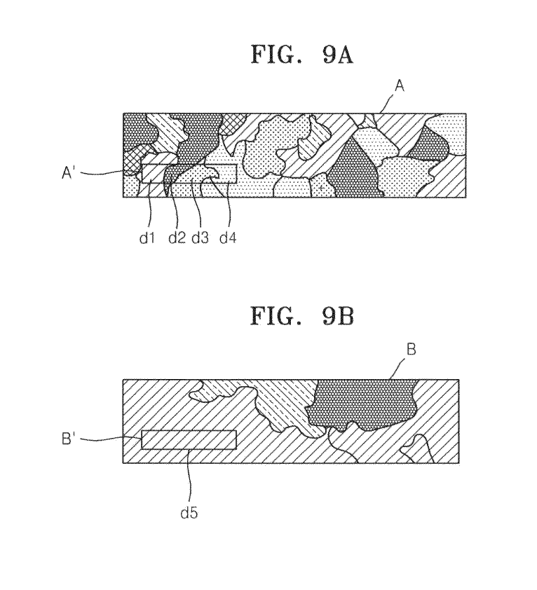

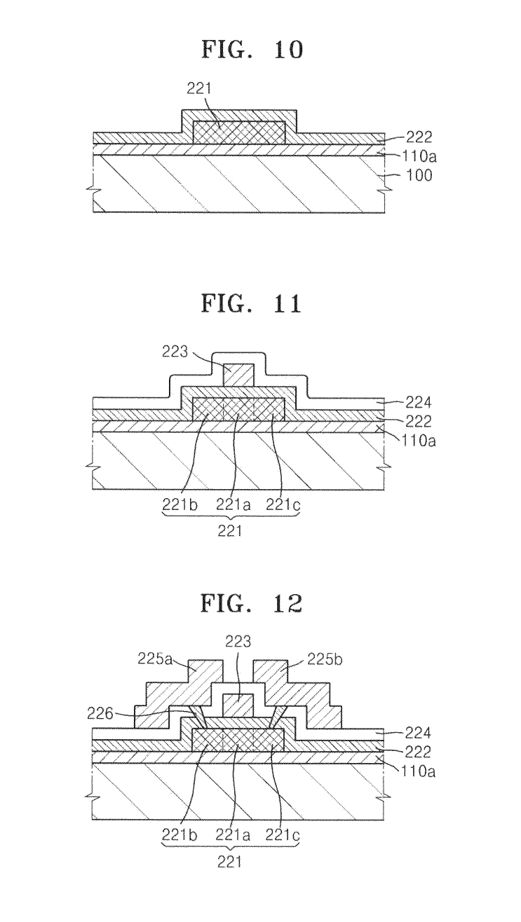

FIGS. 10 through 12 illustrate sectional views to explain a method of manufacturing a thin-film transistor TR by SGS crystallization, according to an embodiment, and FIG. 13 illustrates a schematic sectional view of an organic light-emitting display device including the thin-film transistor TR according to an embodiment.

Referring to FIG. 10, the present embodiment uses a semiconductor layer 221 that may be formed by patterning the polycrystalline silicon layer 220 that is crystallized using the metallic catalyst 141 after the buffer layer 110 is treated with hydrogen plasma. Accordingly, neighboring crystal grains in the semiconductor layer 221 may have similar crystal directions.

A gate insulating layer 222 may be formed on a buffer layer 110a, covering the semiconductor layer 221. The gate insulating layer 222 may be a single layer or a plurality of layers, formed of an inorganic insulating material, such as silicon oxide or silicon nitride.

Referring to FIG. 11, a gate electrode 223 may be formed on the gate insulating layer 222, corresponding to a channel region 221a of the semiconductor layer 221, and an interlayer insulating layer 224 may be formed corresponding to the gate electrode 223.

The semiconductor layer 221 may be divided into the channel region 221a and source and drain regions 221b and 221c. The semiconductor layer 221 may be formed by doping the source and drain regions 221b and 221c with N or P-type impurities into by using the gate electrode 223 as a self align mask, after the gate electrode 223 is formed. Alternatively, the semiconductor layer 221 may be formed by doping impurities directly after the formation of the semiconductor layer 221, which is described in connection with FIG. 10.

Referring to FIG. 12, a source electrode 225a and a drain electrode 225b may be formed on the interlayer insulating layer 224 and respectively contact the source region 221b and the drain region 221c through contact holes.

Referring to FIG. 13, a passivation layer 227 may be formed on the interlayer insulating layer 224, covering the thin film transistor TR. The passivation layer 227 may be a single- or multi-layered insulating layer having an even upper surface. The passivation layer 227 may be formed of an insulating material and/or organic material.

A via-hole exposing the drain electrode 225b of the thin-film transistor TR may be formed through the passivation layer 227. Through the via-hole, a pixel electrode 310 patterned on the passivation layer 227 may be electrically connected to the thin-film transistor TR.

A pixel define layer (PDL) 320 may be formed on the passivation layer 227, covering an edge of the pixel electrode 310. The PDL 320 may cover the edge of the pixel electrode 310 and define a pixel. In addition, the PDL 320 may increase a distance between an end of the pixel electrode 310 and an opposite electrode 340, which will be described below, thereby preventing occurrence of an arc at the end of the pixel electrode 310.

An organic layer 330, including an emissive layer 331, and the opposite electrode 340 may be sequentially formed on the pixel electrode 310.

The organic layer 330 may be a low molecular weight or a polymer organic layer. If the organic layer 330 is a low molecular weight organic layer, the organic layer 330 may include at least one of a hole injection layer (HIL), a hole transport layer (HTL), an emissive layer (EML) 331, an electron transport layer (ETL), and an electron injection layer (EIL), each of which may have a single or multi-layered structure, and an available organic material may be copper phthalocyanine (CuPc), N,N′-Di(naphthalene-1-yl)-N,N′-diphenyl-benzidine (NPB), or tris-8-hydroxyquinoline aluminum (Alq3).

If the organic layer 330 is polymer organic layer, the organic layer 330 may include a HTL formed in a direction toward the pixel electrode 310 from the emissive layer 331. The HTL may be formed of poly-(2,4)-ethylene-dihydroxy thiophene (PEDOT) or polyaniline (PANI). The EML may be formed in each of the red, green, and blue pixels, and the HIL, the HTL, the ETL, and the EIL may be common layers shared by the red, green, and blue pixels.

An encapsulation substrate 400 may prevent permeation of external gas or water molecules into the organic layer 330 including the emissive layer 331. The substrate 100 may be combined with the encapsulation substrate 400 by using a sealing material present along edges thereof.

In the thin-film transistor TR including the semiconductor layer 221 formed by crystallizing the amorphous silicon layer 120 into the polycrystalline silicon layer 220 using the metallic catalyst 141 after the buffer layer 110 is treated with hydrogen plasma, neighboring crystal grains may have the same crystal direction. On the other hand, in a thin-film transistor including a semiconductor layer formed by crystallizing an amorphous silicon layer into a polycrystalline silicon layer using a metallic catalyst after a buffer layer is treated with hydrogen plasma, neighboring crystal grains may randomly grow in a radial direction using a metal seed as a crystallizing nucleus and neighboring crystal grains may have different crystal directions.

The crystal directions of neighboring crystal grains may affect characteristics of a semiconductor device. For example, if crystal grains in a semiconductor layer have different crystal directions, a thin-film transistor including the semiconductor layer may have different electrical characteristics.

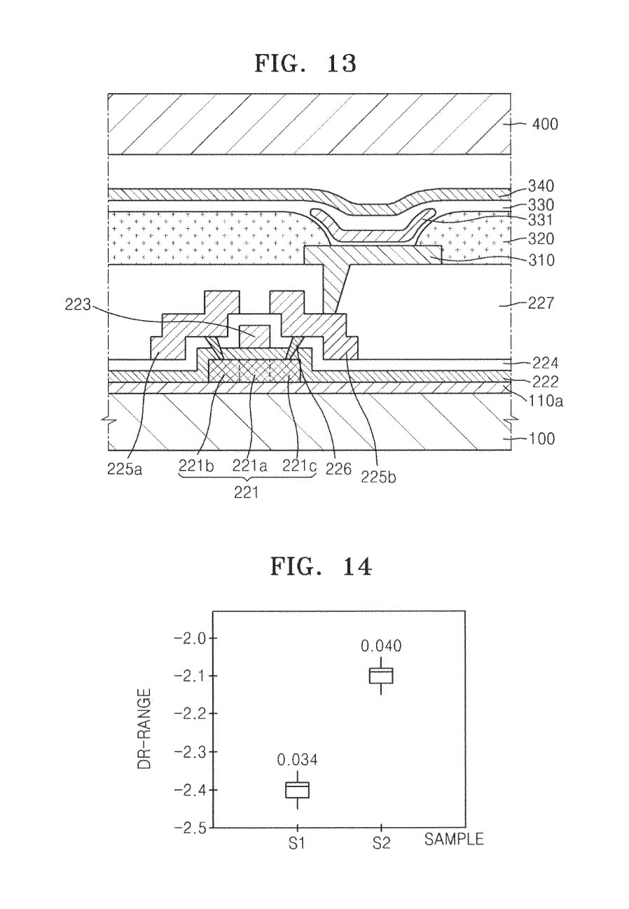

FIG. 14 is a graph showing DR RANGE characteristics of a thin film transistor. Referring to FIG. 14, sample 1 S1 is a thin-film transistor including a semiconductor layer that is crystallized into a polycrystalline silicon from an amorphous silicon using a metallic catalyst after a buffer layer is treated with hydrogen plasma, as in the present embodiment, and sample 2 S2 is a reference sample in which a thin film transistor including a semiconductor layer is crystallized into a polycrystalline silicon from an amorphous silicon using a metallic catalyst after a buffer layer is treated with hydrogen plasma.

DR RANGE is a difference between a gate voltage Vg at a drain current Id of 1 nA and a gate voltage Vg at a drain current Id of 100 nA. The DR RANGE of sample 2 S2 is 1.040 and the DR RANGE of sample 1 S1 according to the present embodiment is 0.034, which is lower than that of sample 2 S2.

Such results are related to crystal directions of neighboring crystal grains in a crystallized semiconductor layer, and without being bound to any particular theory, may be due to the fact that in sample 2 S2, neighboring crystal grains have different crystal directions and in sample 1 S1, neighboring crystal grains have the same crystal direction.

If such a characteristic is applied to a display device, the brightness of neighboring pixels may also be affected. For example, compared to a display device including the thin-film transistor (sample 2 S2) including a semiconductor layer in which neighboring crystal grains have different crystal directions, a display device including the thin-film transistor (sample 1 S1) including a semiconductor layer in which neighboring crystal grains have the same crystal direction may have a more stable brightness.

Although in the present embodiment, an organic light-emitting display device was used as an example of a display device including the thin-film transistor described above, the present invention is not limited thereto and all kinds of display devices, including a liquid crystal display device, may also be used.

As described above, when the methods of forming a polycrystalline silicon layer in which neighboring crystal grains have the same crystal direction and a thin-film transistor according to the above embodiments of the present invention are used, the DR RANGE distribution of a thin-film transistor may be reduced, electrical characteristics of a thin-film transistor are improved, and a display quality of a display device may be improved.

While aspects of the present invention have been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a polycrystalline layer, the method comprising:
forming a buffer layer on a substrate;
treating the buffer layer with hydrogen plasma;
forming an amorphous silicon layer on the buffer layer;
forming a metallic catalyst layer for crystallizing the amorphous silicon layer on the amorphous silicon layer; and
heat treating the amorphous silicon layer to form a polycrystalline silicon layer.

2. The method as claimed in claim 1, wherein the buffer layer formed on the substrate comprises at least one of silicon oxide, silicon nitride, and silicon oxynitride.

3. The method as claimed in claim 1, wherein a surface concentration of the metallic catalyst layer formed on the amorphous silicon layer is in a range of 10¹¹ to 10¹⁵ atoms/cm².

4. The method as claimed in claim 1, wherein the metallic catalyst layer formed on the amorphous silicon layer comprises at least one of Ni, Pd, Ti, Ag, Al, Sn, Sb, Cu, Co, Mo, Tb, Ru, Rh, Cd, and Pt.

5. A thin-film transistor comprising:
a substrate;
a buffer layer comprising hydrogen on the substrate;
a semiconductor layer on the buffer layer, the semiconductor layer comprising a channel region and source and drain regions neighboring the channel region, and comprising a plurality of crystal grains crystallized from amorphous silicon using a metallic catalyst as a seed, wherein at least two neighboring crystal grains have the same crystal direction;
a gate insulating layer on the buffer layer and covering the semiconductor layer;
a gate electrode that is formed on the gate insulating layer, corresponding to the channel region;
an interlayer insulating layer on the gate insulating layer and covering the gate electrode; and
source and drain electrodes that are formed on the interlayer insulating layer and electrically connected to the source region and the drain region, respectively.

6. The thin-film transistor as claimed in claim 5, wherein the buffer layer comprises at least one of silicon oxide, silicon nitride, and silicon oxynitride.

7. The thin-film transistor as claimed in claim 5, wherein the metallic catalyst is at least one of Ni, Pd, Ti, Ag, Al, Sn, Sb, Cu, Co, Mo, Tb, Ru, Rh, Cd, and Pt.

8. The thin-film transistor as claimed in claim 5, wherein the semiconductor layer has more neighboring crystal grains having a same crystal direction than does a semiconductor layer that is formed on a buffer layer that does not comprise hydrogen.

9. The thin-film transistor as claimed in claim 5, wherein crystal directions of crystal grains of the semiconductor layer have a crystal direction heterogeneity factor D of less than 20 as measured by an electron backscattered diffraction (EBSD) analysis system, according to the formula D=(N/n)×1000, where n is a total number of pixels evaluated in the electron backscattered diffraction (EBSD) analysis system and N is a number of instances in which a crystal direction reference factor, calculated as a maximum difference value among difference values of R, G, and B values of the evaluated pixels, is equal to or greater than 150.

10. A method of forming a thin-film transistor, the method comprising:
forming a buffer layer on a substrate;
treating the buffer layer with hydrogen plasma;
forming an amorphous silicon layer on the buffer layer;
forming a metallic catalyst layer for crystallizing the amorphous silicon layer on the amorphous silicon layer;
heat treating the amorphous silicon layer to form a polycrystalline silicon layer;
removing the metallic catalyst layer and patterning the polycrystalline silicon layer to form a semiconductor layer comprising source and drain regions and a channel region;
forming a gate insulating layer covering the semiconductor layer;
forming a gate electrode on the gate insulating layer, corresponding to the channel region of the semiconductor layer;
forming an interlayer insulating layer covering the gate electrode on the gate insulating layer; and
forming source and drain electrodes disposed on the interlayer insulating layer and electrically connected to the source and drain regions of the semiconductor layer, respectively.

11. The method as claimed in claim 10, wherein the buffer layer formed on the substrate comprises at least one of silicon oxide, silicon nitride, and silicon oxynitride.

12. The method as claimed in claim 10, wherein a surface concentration of the metallic catalyst layer formed on the amorphous silicon layer is in a range of 10¹¹ to 10¹⁵ atoms/cm².

13. The method as claimed in claim 10, wherein the metallic catalyst layer formed on the amorphous silicon layer comprises at least one of Ni, Pd, Ti, Ag, Al, Sn, Sb, Cu, Co, Mo, Tb, Ru, Rh, Cd, and Pt.

14. An organic light-emitting display device, comprising:
a substrate;
a buffer layer comprising hydrogen on the substrate;
a semiconductor layer on the buffer layer, the semiconductor layer comprising a channel region and source and drain regions neighboring the channel region, and comprising a plurality of crystal grains crystallized from an amorphous silicon using a metallic catalyst as a seed, wherein at least two neighboring crystal grains have the same crystal direction;
a gate insulating layer on the buffer layer and covering the semiconductor layer;
a gate electrode on the gate insulating layer, corresponding to the channel region;
an interlayer insulating layer on the gate insulating layer and covering the gate electrode;
source and drain electrodes on the interlayer insulating layer and electrically connected to the source region and the drain region, respectively;
a passivation layer on the gate insulating layer, covering the source and drain electrodes;
a pixel electrode on the passivation layer and is electrically connected to the source electrode or the drain electrode through a via-hole; and
an organic layer on the pixel electrode and comprising an emissive layer.

15. The organic light-emitting display device as claimed in claim 14, wherein the buffer layer comprises silicon oxide, silicon nitride, or silicon oxynitride.

16. The organic light-emitting display device as claimed in claim 14, wherein the metallic catalyst comprises at least one of Ni, Pd, Ti, Ag, Al, Sn, Sb, Cu, Co, Mo, Tb, Ru, Rh, Cd, and Pt.

17. The thin-film transistor as claimed in claim 14, wherein the semiconductor layer has more neighboring crystal grains having a same crystal direction than does a semiconductor layer that is formed on a buffer layer that does not comprise hydrogen.

18. The organic light-emitting display device as claimed in claim 14, wherein crystal directions of crystal grains of the semiconductor layer have a crystal direction heterogeneity factor D of less than 20, as measured by an electron backscattered diffraction (EBSD) analysis system, according to the formula D=(N/n)×1000, where n is a total number of pixels evaluated in an electron backscattered diffraction (EBSD) analysis system and N is a number of instances in which a crystal direction reference factor, calculated as a maximum difference value among difference values of R, G, and B values of the evaluated pixels, is equal to or greater than 150.
